(19) United States
(12) Patent Application Publication
(10) Pub. No.: US 2026/0206557 A1
(43) Pub. Date: Jul. 16, 2026

(54) FEATURE FILL USING INHIBITION

(71) Applicant: Lam Research Corporation, Fremont, CA (US)

(72) Inventors: Anand CHANDRASHEKAR, Fremont, CA (US); Son Vo Nam TRAN, Tracy, CA (US)

(21) Appl. No.: 19/137,606

(22) PCT Filed: Dec. 12, 2023
(86) PCT No.: PCT/US2023/083696

§ 371 Date: Jun. 10, 2025

Related U.S. Application Data
(60) Provisional application No. 63/387,493, filed on Dec. 14, 2022.

(51) Int. Cl. H10W 20/00; C23C 16/04; C23C 16/06; C23C 16/455; C23C 16/52; H01J 37/32

(52) U.S. Cl. CPC H10W 20/056; C23C 16/045; C23C 16/06; C23C 16/45519; C23C 16/45527; C23C 16/45544; C23C 16/52; H01J 37/32449; H10W 20/033; H01J 2237/3321

(57) ABSTRACT

Provided herein are methods of filling features with metal including inhibition of metal nucleation

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in their entireties and for all purposes.

### BACKGROUND

Deposition of metals in features is an integral part of many semiconductor fabrication processes. The deposited metal films may be used for horizontal interconnects, vias between adjacent metal layers, and contacts between metal layers and devices. In an example of deposition, a tungsten (W) layer may be deposited on a titanium nitride (TiN) barrier layer to form a TiN/W bilayer by a chemical vapor deposition (CVD) process using tungsten hexafluoride (WF₆). However, as devices shrink and more complex patterning schemes are utilized in the industry, deposition of thin metal films becomes a challenge. The continued decrease in feature size and film thickness brings various challenges to filling features with a void free film. Deposition in complex high aspect ratio structures is particularly challenging.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided herein are methods of filling features with metal including inhibition of metal nucleation. One aspect of the disclosure relates to a method including:
a) providing a feature to be filled with metal, the feature including a feature opening and sidewalls extending from the feature opening to a process station; and
b) exposing the feature to a metal precursor, a reducing agent, and a nitrogen-containing gas to fill the feature with metal, wherein the nitrogen-containing gas inhibits metal deposition on surfaces of the sidewalls it contacts.

In some embodiments, a flow of the nitrogen-containing gas is decreased as more metal is deposited in the feature.

In some embodiments, the method further includes, prior to (b), forming a liner of metal in the feature.

In some embodiments, the method further includes, prior to (b), exposing the feature to the nitrogen-containing gas without significant deposition to inhibit deposition of the metal near the feature opening.

In some embodiments, (b) includes continuously co-flowing the metal precursor, the reducing agent, and the nitrogen-containing gas into the process station.

In some such embodiments, the method further includes, prior to (b), exposing the feature to the nitrogen-containing gas without significant deposition to inhibit deposition of the metal near the feature opening.

In some such embodiments, a flow of the reducing agent is ramped up and a flow of the nitrogen-containing gas is ramped down as (b) progresses.

In some embodiments, (b) includes continuously flowing the metal precursor into the process station while pulsing the reducing agent and the nitrogen-containing gas in alternating sequence.

In some embodiments, (b) includes continuously flowing the nitrogen-containing gas into the process station containing the substrate while pulsing the metal precursor and the reducing agent into the process station.

In some embodiments, the metal precursor and the reducing agent are pulsed together into the process station.

In some embodiments, pulses of the metal precursor and pulses of the reducing agent are alternated.

In some embodiments, (b) includes continuously flowing the reducing agent into the process station containing the substrate while pulsing the metal precursor and nitrogen-containing gas into the process station.

In some embodiments, the metal precursor and nitrogen-containing gas are pulsed together into the process station.

In some embodiments, pulses of the metal precursor and pulses of the nitrogen-containing gas are alternated.

In some embodiments, the metal is one of a tungsten (W), molybdenum (Mo), ruthenium (Ru), or cobalt (Co).

In some embodiments, the nitrogen-containing gas is ammonia.

Another aspect of the disclosure relates to an apparatus including:
a process station including a showerhead to direct gases to a substrate support;
a controller configured to execute machine-readable instructions for filling a feature with metal, the instructions including instructions for: (a) causing flowing of a metal precursor, a reducing agent, and a nitrogen-containing gas into the process station to fill the feature with metal.

In some embodiments, the instructions for (a) cause continuous co-flowing of the metal precursor, the reducing agent, and the nitrogen-containing gas into the process station.

In some embodiments, the instructions further include instructions for, prior to (a), causing flowing of the nitrogen-containing gas without flowing of the reducing agent to inhibit metal deposition near the feature opening.

In some embodiments, the instructions further include instructions for causing ramping up of flowing of the reducing agent flow and ramping down of flowing of the nitrogen-containing gas as (a) progresses.

These and other aspects of the disclosure are discussed further below with reference to the drawings.

### BRIEF DESCRIPTION OF FIGURES

FIGS. 1A and 1B are schematic examples of material stacks that include a conductive metal layer according to various embodiments.

FIGS. 2A-2K are schematic examples of various structures into which a metal fill layer may be deposited in accordance with disclosed embodiments.

FIG. 3A is a process flow diagram illustrating operations in filling a structure with a metal according to various embodiments.

FIG. 3B shows a schematic of a cross-section of feature at various stages in according to an embodiment of the process in FIG. 3A.

FIG. 4 shows a schematic of a cross-section of feature at various stages of fill.

FIG. 5 shows an example of a process flow diagram illustrating operations in a method of filling a feature with metal.

FIG. 6 shows a schematic of a cross-section of feature at various stages in according to an embodiment of the process in FIG. 5.

FIGS. 7 and 8 illustrate examples of various ramped flow profiles.

FIGS. 9-11 shows schematics of apparatus that may be used in accordance with certain embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

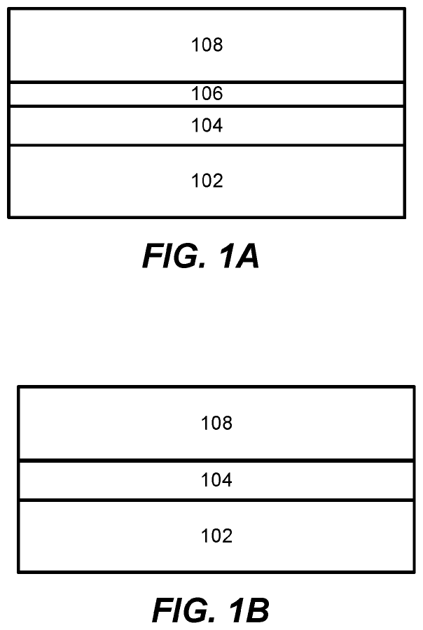

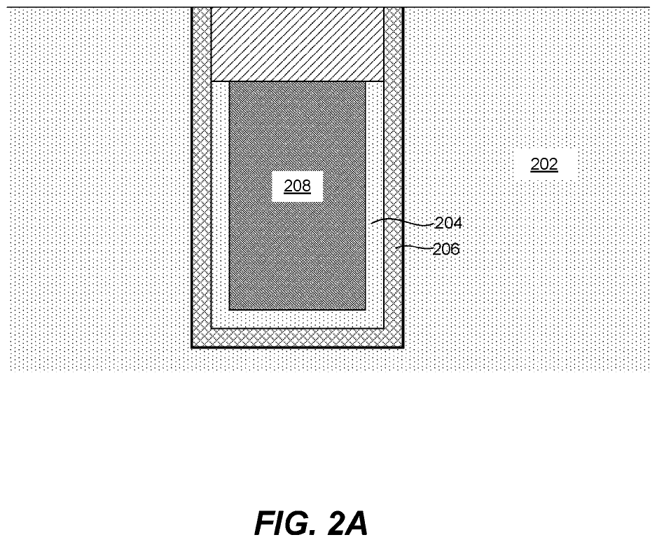

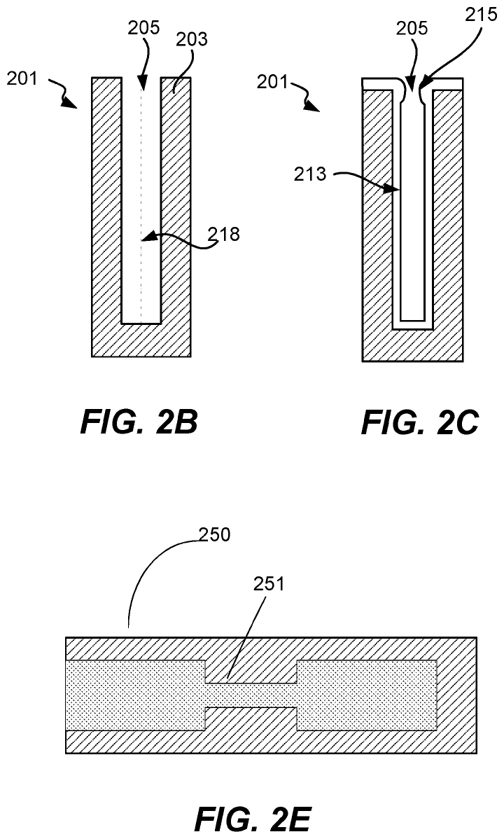

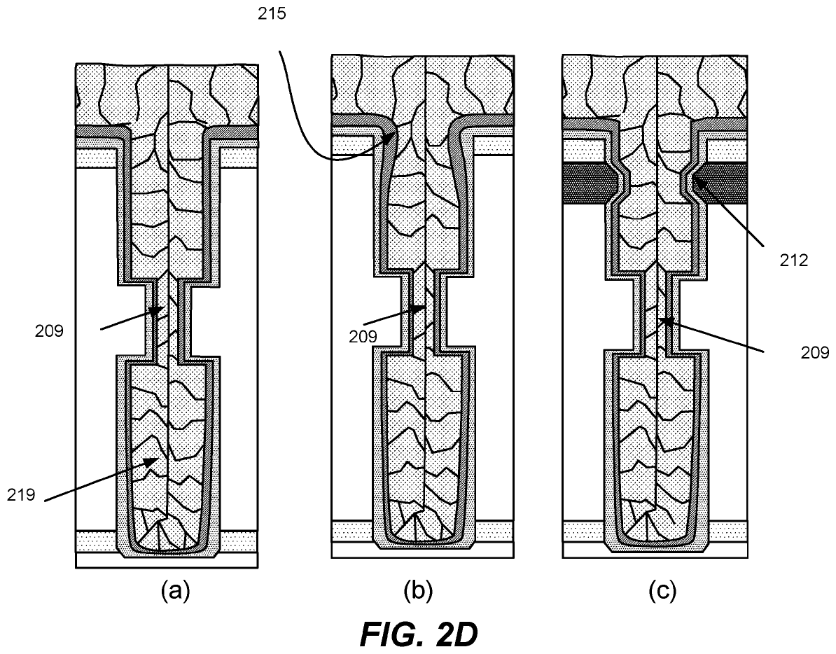

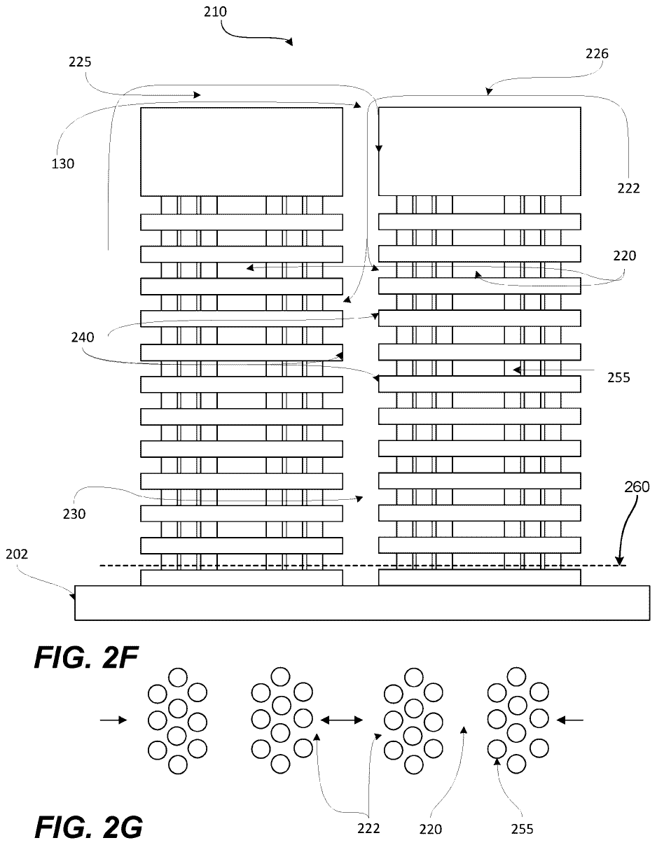

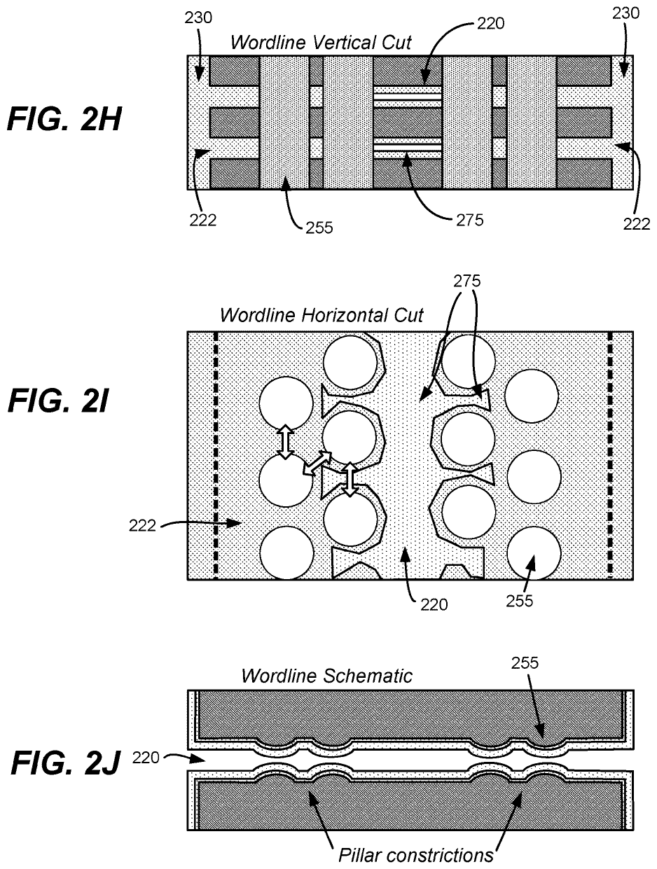

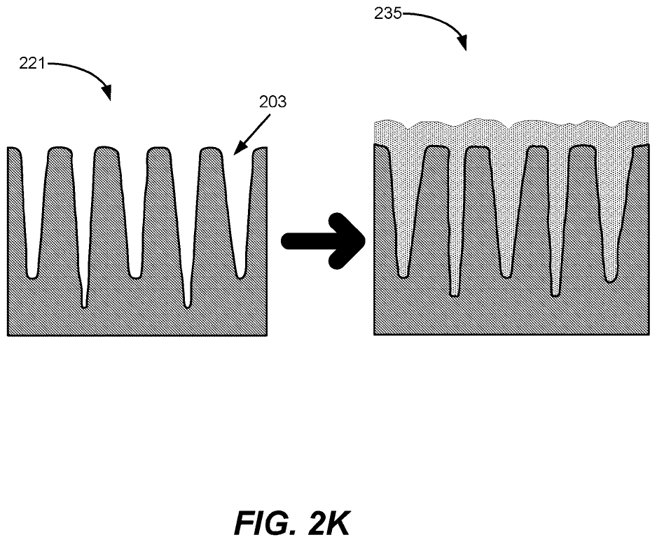

Provided herein are methods of filling features with metal such as tungsten (W), molybdenum (Mo), cobalt (Co), and ruthenium (Ru) that may be used for logic and memory applications. FIGS. 1A and 1B are schematic examples of material stacks that include a conductive metal layer according to various embodiments. FIGS. 1A and 1B illustrate the order of materials in a particular stack and may be used with any appropriate architecture and application, as described further below with respect to FIGS. 2A-2K. In the example of FIG. 1A, a substrate 102 has a conductive metal layer 108 deposited thereon. The substrate 102 may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to form metallization stack structures on other substrates, such as glass, plastic, and the like.

In FIG. 1A, a dielectric layer 104 is on the substrate 102. The dielectric layer 104 may be deposited directly on a semiconductor (e.g., silicon (Si)) surface of the substrate 102, or there may be any number of intervening layers. Examples of dielectric layers include doped and undoped silicon oxide (SiO₂), silicon nitride, and aluminum oxide (Al₂O₃) layers, with specific examples including doped or undoped layers SiO₂ and Al₂O₃. Also, in FIG. 1A, a diffusion barrier layer 106 is disposed between the conductive metal layer 108 and the dielectric layer 104. Examples of diffusion barrier layers including titanium nitride (TiN), titanium/titanium nitride (Ti/TiN), tungsten nitride (WN), and tungsten carbon nitride (WCN). Further examples of diffusion barriers are multi-component Mo-containing films such as molybdenum nitride (MoN). The conductive metal layer 108 is the main conductor of the structure. In some embodiments, the conductive metal layer 108 may include multiple bulk layers deposited at different conditions. The conductive metal layer 108 may or may not include a nucleation layer, e.g., the conductive metal layer 108 may include a W bulk layer deposited on W nucleation layer. In some embodiments, a metal layer of one metal (e.g., Mo) may be deposited on a thin growth initiation layer of another metal (e.g., W).

FIG. 1B shows another example of a material stack. In this example, the stack includes the substrate 102, dielectric layer 104, with conductive metal layer 108 deposited directly on the dielectric layer 104, without an intervening diffusion barrier layer. The conductive metal layer 108 is as described with respect to FIG. 1A.

While FIGS. 1A and 1B show examples of metallization stacks, the methods and resulting stacks are not so limited. For example, in some embodiments, the metal conductive layer may be deposited directly on a Si or other semiconductor substrate, with or without a nucleation or initiation layer. FIGS. 1A and 1B illustrate examples of an order of materials in a particular stack and may be used with any appropriate architecture and application, with examples of different applications and architectures described further below with respect to FIGS. 2A-2J.

The methods described herein are performed on a substrate that may be housed in a chamber. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods are not limit to semiconductor substrates and may be performed to fill any feature with a metal-containing material.

Substrates may have features such as via or contact holes, which may be characterized by one or more of narrow and/or re-entrant openings, constrictions within the feature, and high aspect ratios. A feature may be formed in one or more of the above-described layers. For example, the feature may be formed at least partially in a dielectric layer. In some embodiments, a feature may have an aspect ratio of at least about 2:1, at least about 4:1, at least about 6:1, at least about 10:1, at least about 25:1, or higher. One example of a feature is a hole or via in a semiconductor substrate or a layer on the substrate.

FIG. 2A depicts a schematic example of a DRAM architecture including a metal buried wordline (bWL) 208 in a silicon substrate 202. The metal bWL is formed in a trench etched in the silicon substrate 202. Lining the trench is a conformal barrier layer 206 and an insulating layer 204 that is disposed between the conformal barrier layer 206 and the silicon substrate 202. In the example of FIG. 2A, the insulating layer 204 may be a gate oxide layer, formed from a high-k dielectric material such as a silicon oxide or silicon nitride material. In some embodiments disclosed herein the conformal barrier layer is TiN or tungsten-containing layer. In some embodiments, one or both of insulating layer 204 and conformal barrier layer 206 is or are not present.

The bWL structure shown in FIG. 2A is one example of an architecture that includes a conductive metal fill layer. During fabrication of the bWL, a conductive metal film is deposited into a feature that may be defined by an etched recess in the silicon substrate 202 that is conformally lined with conformal barrier layer 206 and insulating layer 204, if present.

FIGS. 2B-2H are additional schematic examples of various structures into which a metal fill layer may be deposited in accordance with disclosed embodiments. FIG. 2B shows an example of a cross-sectional depiction of a vertical feature 201 to be filled with metal. The feature can include a feature hole 205 in a substrate 203. The hole 205 or other feature may have a dimension near the opening, e.g., an opening diameter or line width of about 10 nm to about 500 nm, for example about 25 nm to about 300 nm. The feature hole 205 can be referred to as an unfilled feature or simply a feature. The feature 201, and any feature, may be characterized in part by an axis 218 that extends through the length of the feature, with vertically-oriented features having vertical axes and horizontally-oriented features having horizontal axes.

In some embodiments, features are wordline features in a 3-D NAND structure. For example, a substrate may include a wordline structure having an arbitrary number of wordlines (e.g., 50 to 150) with vertical channels at least 200 Å deep. Another example is a trench in a substrate or layer. Features may be of any depth. In various embodiments, the feature may have an under-layer, such as a barrier layer or adhesion layer. Non-limiting examples of under-layers include dielectric layers and conducting layers, e.g., silicon oxides, silicon nitrides, silicon carbides, metal oxides, metal nitrides, metal carbides, and metal layers.

FIG. 2C shows an example of a feature 201 that has a re-entrant profile. A re-entrant profile is a profile that narrows from a bottom, closed end, or interior of the feature to the feature opening. According to various implementations, the profile may narrow gradually and/or include an overhang at the feature opening. FIG. 2C shows an example of the latter, with an under-layer 213 lining the sidewall or interior surfaces of the feature hole 205. The under-layer 213 can be for example, a diffusion barrier layer, an adhesion layer, a nucleation layer, a combination of thereof, or any other applicable material. Non-limiting examples of under-layers can include dielectric layers and conducting layers, e.g., silicon oxides, silicon nitrides, silicon carbides, metal oxides, metal nitrides, metal carbides, and metal layers. In particular implementations, an under-layer 213 can be one or more of titanium, titanium nitride, tungsten nitride, titanium aluminide, tungsten, and molybdenum. In some embodiments, the under-layer 213 is different from or does not contain the metal of the metal conductive layer. In some embodiments, the under-layer 213 is tungsten-free. In some embodiments, the under-layer 213 is molybdenum-free. The under-layer 213 forms an overhang 215 such that the under-layer 213 is thicker near the opening of the feature 201 than inside the feature 201.

In some implementations, features having one or more constrictions within the feature may be filled. FIG. 2D shows examples of views of various filled features having constrictions. Each of the examples (a), (b) and (c) in FIG. 2D includes a constriction 209 at a midpoint within the feature. The constriction 209 can be, for example, about 15 nm to about 20 nm wide. Constrictions can cause pinch off during deposition of tungsten or molybdenum in the feature using conventional techniques, with deposited metal blocking further deposition past the constriction before that portion of the feature is filled, resulting in voids in the feature. Example (b) further includes a liner/barrier overhang 215 at the feature opening. Such an overhang could also be a potential pinch-off point. Example (c) includes a constriction 212 further away from the field region than the overhang 215 in example (b).

Horizontal features, such as in 3-D memory structures, can also be filled. FIG. 2E shows an example of a horizontal feature 250 that includes a constriction 251. For example, horizontal feature 250 may be a word line in a 3-D NAND (also referred to as vertical NAND or VNAND) structure. In some implementations, the constrictions can be due to the presence of pillars in a 3-D NAND or other structure. FIG. 2F presents a cross-sectional side-view of a 3-D NAND structure 210 (formed on a silicon substrate 202) having VNAND stacks (left 225 and right 226), central vertical structure 230, and a plurality of stacked horizontal features 220 with openings 222 on opposite sidewalls 240 of central vertical structure 230. Note that FIG. 2F displays two “stacks” of the exhibited 3-D NAND structure 210, which together form the “trench-like” central vertical structure 230; however, in certain embodiments, there may be more than two “stacks” arranged in sequence and running spatially parallel to one another, the gap between each adjacent pair of “stacks” forming a central vertical structure 230, like that explicitly illustrated in FIG. 2F. In this embodiment, the horizontal features 120 are 3-D memory wordline features that are fluidically accessible from the central vertical structure 230 through the openings 222. Although not explicitly indicated in the figure, the horizontal features 220 present in both the 3-D NAND stacks 225 and 226 shown in FIG. 2F (i.e., the left 3-D NAND stack 225 and the right 3-D NAND stack 226) are also accessible from the other sides of the stacks (far left and far right, respectively) through similar vertical structures formed by additional 3-D NAND stacks (to the far left and far right, but not shown). In other words, each 3-D NAND stack 225, 226 contains a stack of wordline features that are fluidically accessible from both sides of the 3-D NAND stack through a central vertical structure 1230. In the particular example schematically illustrated in FIG. 2F, each 3-D NAND stack contains 6 pairs of stacked wordlines, however, in other embodiments, a 3-D NAND memory layout may contain any number of vertically stacked pairs of wordlines.

The wordline features in a 3-D NAND stack are typically formed by depositing an alternating stack of silicon oxide and silicon nitride layers, and then selectively removing the nitride layers, leaving a stack of oxide layers having gaps between them. These gaps are the wordline features. Any number of wordlines may be vertically stacked in such a 3-D NAND structure so long as there is a technique for forming them available, as well as a technique available to successfully accomplish (substantially) void-free fills of the vertical features. Thus, for example, a VNAND stack may include between 2 and 256 horizontal wordline features, or between 8 and 128 horizontal wordline features, or between 16 and 64 horizontal wordline features, and so forth (the listed ranges understood to include the recited end points).

FIG. 2G presents a cross-sectional top-down view of the same 3-D NAND structure 210 shown in side-view in FIG. 2F with the cross-section taken through the horizontal section 260 as indicated by the dashed horizontal line in FIG. 2F. The cross-section of FIG. 2G illustrates several rows of pillars 255, which are shown in FIG. 1F to run vertically from the base of semiconductor substrate 202 to the top of 3-D NAND stack 210. In some embodiments, these pillars 255 are formed from a polysilicon material and are structurally and functionally significant to the 3-D NAND structure 210. In some embodiments, such polysilicon pillars may serve as gate electrodes for stacked memory cells formed within the pillars. The top-view of FIG. 2G illustrates that the pillars 255 form constrictions in the openings 222 to wordline features 220—i.e. fluidic accessibility of wordline features 220 from the central vertical structure 230 via openings 222 (as indicated by the arrows in FIG. 2G) is inhibited by pillars 255. In some embodiments, the size of the horizontal gap between adjacent polysilicon pillars is between about 1 and 20 nm. This reduction in fluidic accessibility increases the difficulty of uniformly filling wordline features 120 with conductive metal film. The structure of wordline features 220 and the challenge of uniformly filling them with conductive metal material due to the presence of pillars 255 are further illustrated in FIGS. 2H, 2I, and 2J.

FIG. 2H exhibits a vertical cut through a 3-D NAND structure similar to that shown in FIG. 2F, but here focused on a single pair of wordline features 220 and additionally schematically illustrating a fill process which resulted in the formation of a void 275 in the filled wordline features 220. FIG. 2I also schematically illustrates void 275, but in this figure illustrated via a horizontal cut through pillars 255, like the horizontal cut exhibited in FIG. 2G. FIG. 2J illustrates the accumulation of metal (e.g., W or Mo) around the constriction-forming pillars 255, the accumulation resulting in the pinch-off of openings 222, so that no additional W, Mo, or other metal can be deposited in the region of voids 275. Apparent from FIGS. 2H and 2I is that void-free fill relies on migration of sufficient quantities of deposition precursor down through vertical structure 230, through openings 222, past the constricting pillars 255, and into the furthest reaches of wordline features 220, prior to the accumulated deposition of metal around pillars 255 causing a pinch-off of the openings 222 and preventing further precursor migration into wordline features 220. Similarly, FIG. 2J exhibits a single wordline feature 220 viewed cross-sectionally from above and illustrates how a generally conformal deposition of metal begins to pinch-off the interior of wordline feature 220 due to the fact that the significant width of pillars 255 acts to partially block, and/or narrow, and/or constrict what would otherwise be an open path through wordline feature 220. (It should be noted that the example in FIG. 2J can be understood as a 2-D rendering of the 3-D features of the structure of the pillar constrictions shown in FIG. 2I, thus illustrating constrictions that would be seen in a plan view rather than in a cross-sectional view.) Three-dimensional structures may need longer and/or more concentrated exposure to precursors to allow the innermost and bottommost areas to be filled.

In some embodiments, the methods involve deposition of a first metal layer in a feature. The first metal layer may be a nucleation layer, a bulk layer, or a bulk layer deposited on a nucleation layer. It may be deposited by an ALD process to conformally line the feature. The first metal layer may be exposed to an inhibition treatment. In some embodiments, the inhibition treatment is preferentially applied near the top of the feature, such that subsequent deposition in the bottom of the feature is not inhibited or inhibited to a lesser extent than near the top. This results in bottom-up fill.

The methods may also be used to fill multiple adjacent features, such as DRAM bWL trenches. Fill processes for DRAM bWL trenches can distort the trenches such that the final trench width and resistance Rs are significantly non-uniform. This phenomenon is referred to as line bending. FIG. 2K shows an unfilled (231) and filled (235) narrow asymmetric trench structure DRAM bWL that exhibit line bending after fill. As shown, multiple features are depicted on a substrate. These features are spaced apart, and in some embodiments, adjacent features have a pitch between about 20 nm and about 60 nm or between about 20 nm and 40 nm. The pitch is defined as the distance between the middle axis of one feature to the middle axis of an adjacent feature. The unfilled features may be generally V-shaped as shown in feature 203, having sloped sidewalls where the width of the feature narrows from the top of the feature to the bottom of the feature. The features widen from the feature bottom to the feature top. Sequences of depositions that use inhibition may be used to mitigate line bending. These include inhibiting the full depth of the features.

Examples of feature fill for horizontally-oriented and vertically-oriented features are described below. It should be noted that in at least most cases, the examples are applicable to both horizontally-oriented or vertically-oriented features. Moreover, it should also be noted that in the description below, the term “lateral” or “horizontal” may be used to refer to a direction generally orthogonal to the feature axis and the term “vertical” to refer to a direction generally along the feature axis.

Embodiments of the methods described herein employ plasmas including oxygen species to modulate or remove a nucleation inhibition effect. In some embodiments, they may be implemented as part of a deposition-inhibition-deposition (DID) sequence for feature fill.

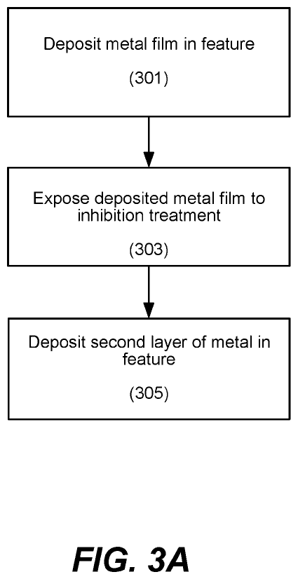

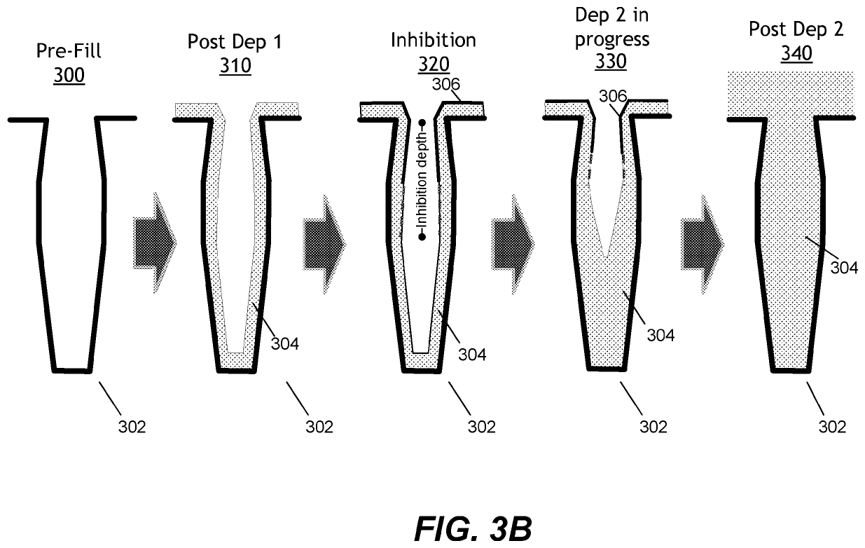

FIG. 3A is a process flow diagram illustrating operations in filling a structure with a metal according to various embodiments and FIG. 3B shows a schematic of a cross-section of a feature at various stages according to an embodiment of the process in FIG. 3A.

In FIG. 3B, at 300, an unfilled feature 302 is shown at a pre-fill stage. The feature 302 may be formed in one or more layers on a semiconductor substrate and may optionally have one or more layers that line the sidewalls and/or bottom of the feature 302. Turning to FIG. 3A, a metal film is deposited in the feature in an operation 301. This operation may be referred to as Dep1. In many embodiments, operation 301 is a generally conformal deposition that lines the exposed surfaces of the structures. For example, in a 3-D NAND structure such as that shown in FIG. 2F, the metal film lines the wordline features 220. According to various embodiments, the metal film is deposited using an atomic layer deposition (ALD) process to achieve good conformality. Chemical vapor deposition (CVD) processes may be used in alternate embodiments. Still further, the process may also be carried out with any appropriate metal deposition including physical vapor deposition (PVD) or plating processes. In some embodiments, after operation 301, the features are not closed off, but sufficiently open to allow further reactant gases to enter the features in a subsequent deposition.

In an ALD process, the feature is exposed to alternating pulses of reactant gases. In the example of tungsten deposition, a tungsten-containing precursor such as tungsten hexafluoride (WF₆), tungsten hexachloride (WCl₆), tungsten pentachloride (WCl₅), tungsten hexacarbonyl (W(CO)₆), or a tungsten-containing organometallic compound may be used. In some embodiments, pulses of the tungsten-containing precursor are pulsed with a reducing agent such as hydrogen (H₂), diborane (B₂H₆), silane (SiH₄), or germane (GeH₄). In a CVD method, the wafer is exposed to the reactant gases simultaneously. Deposition chemistries for other films are provided below. In FIG. 3B, at 310, the feature 302 is shown after Dep1 to form a layer of the material 304 to be filled in the feature 302.

Next, in an operation 303 in FIG. 3A, the deposited metal film is exposed to an inhibition treatment. This may be a conformal or non-conformal treatment. A non-conformal treatment in this context refers to the treatment being preferentially applied at and near the opening or openings of the feature rather than in the feature interior. For 3-D NAND structures, the treatment may be conformal in the vertical direction such that the bottom wordline feature is treated to approximately the same extent as the top wordline feature, while non-conformal in that the interior of the wordline features are not exposed to the treatment or to a significantly lesser extent than the feature openings. A conformal treatment refers to the entire feature being treated to roughly the same extent. Such a treatment may be performed to mitigate line bending, for example, of the features in FIG. 2K.

The inhibition treatment treats the feature surface to inhibit subsequent metal nucleation at the treated surfaces. It can involve one or more of: deposition of an inhibition film, reaction of plasma species with the Dep1 film to form a compound film (e.g., WN or Mo₂N), and adsorption of inhibition species. During the subsequent deposition operation, there is a nucleation delay on the inhibited portions of the underlying film relative to the non- or lesser-inhibited portions (if any). Operation 303 may be a non-plasma treatment. In some embodiments, a plasma operation may be used instead of a plasma operation. If a non-plasma operation, it may be purely thermal or activated by some other energy such as UV.

For thermal inhibition treatments, a nitrogen- and hydrogen-containing compound such as ammonia (NH₃) may be used. A thermal inhibition treatment may involve flowing a metal precursor, however, there is no significant deposition. If there is any deposition, it may be discontinuous or less than a monolayer, for example.

In FIG. 3B, at 320, the feature 302 is shown after an inhibition treatment. The inhibition treatment is a treatment that has the effect of inhibiting subsequent deposition on the treated surfaces 306. The inhibition may be characterized by an inhibition depth and an inhibition gradient. For non-conformal inhibitions, the inhibition varies with feature depth, e.g., such that the inhibition is greater at the feature opening than at the bottom of the feature, and may extend only partway into the feature. In the depicted example of FIG. 3B, the inhibition depth is about half of the full feature depth. In addition, the inhibition treatment is stronger at the top of the feature, as graphically shown by the dotted line deeper within the feature. As indicated above, in other embodiments, the inhibition may be uniform throughout the feature.

Returning to FIG. 3A, after operation 303, a second layer of metal is deposited in the feature in an operation 305. The second deposition may be referred to as Dep2 and may be performed by an ALD or CVD process. For deposition into 3-D NAND structures, an ALD process may be used to allow for good step coverage throughout the structure. The Dep2 operation is influenced by the preceding inhibition operation. For example, if the feature openings are preferentially inhibited over the feature interior, deposition will preferentially occur in the feature interior. In another example, nitrogen on the surface of the deposited metal along the sidewalls of the feature may prevent metal-metal (e.g., tungsten-tungsten bonding) thereby reducing line bending.

In the example of FIG. 3B, because deposition is inhibited near the feature opening, during the Dep2 stage shown at 330, the material preferentially deposits at the feature bottom while not depositing or depositing to a lesser extent at the feature opening. This can prevent the formation of voids and seams within the filled feature. As such, during Dep2, the material 304 may be filled in a manner characterized as bottom-up fill rather than the conformal Dep1 fill. As the deposition continues, the inhibition effect may be removed, such that deposition on the lightly treated surfaces may no longer be inhibited. This is illustrated at 330, with the treated surfaces 306 being less extensive than prior to the Dep2 stage. In the example of FIG. 3B, as the Dep2 proceeds, the inhibition is eventually overcome on all surfaces and the feature is completely filled with the material 304 as shown at 340. While the DID process in FIG. 3B shows the feature preferentially inhibited at the top of the feature, in some embodiments, the entire feature may be inhibited. Such a process can be useful for preventing line bending, for example. Returning to FIG. 3A, in some embodiments, operations 303 and 305 may be performed concurrently.

Embodiments of the methods include simultaneous or concurrent inhibition and deposition operations. They may be implemented as part of a DID sequence in some embodiments. In other embodiments, they may be part of any process sequence that includes deposition and inhibition operations.

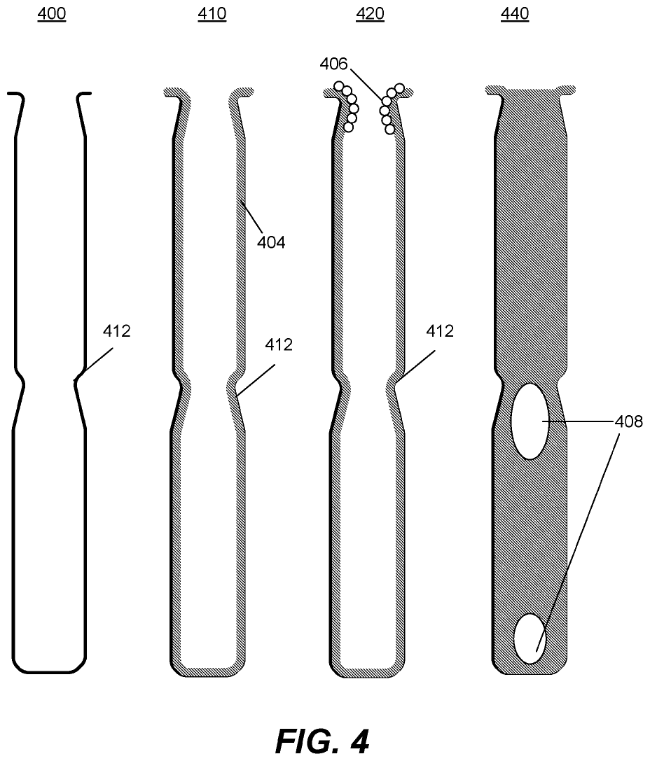

According to various embodiments, the methods may be particularly useful for features having one or more constrictions away from the field region. Examples of these types of features are discussed above with respect to FIG. 2D, for example. Turning to FIG. 4, for example, a feature is shown at various stages of a DID process as described with respect to FIG. 3B. At 400, the feature is shown before fill. At 410, the feature is shown with a conformal layer of metal 404 lining the feature. At 420, the feature is shown after an inhibition process. In this example, small circles represent the treated surfaces 406. The surfaces at and just below the constriction 412 are not treated or treated to a lesser extent that at the top of the feature. At 440, the feature is shown after deposition to fill the feature with metal 404. In this example, however, the presence of the constriction 412 results in voids 408 in the filled feature.

The feature shown in FIG. 4 is an example of a feature having a constriction away from the field region. Significantly more complex features may be filled using the methods described herein, including those having multiple constrictions at different feature depths.

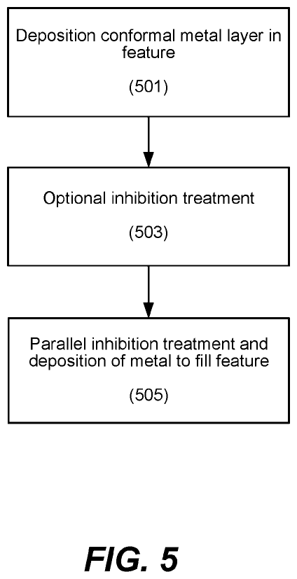

FIG. 5 is a process flow diagram illustrating various operations in a method of filling a feature with metal. In FIG. 5, the process begins with deposition of a conformal metal layer in the feature. This may involve an ALD process, for example, to form a liner layer of the metal in the feature. Then, an optional inhibition treatment is performed in an operation 503. Inhibition treatments are discussed above and generally involve flowing a nitrogen-containing compound such as NH₃. As discussed further below, in some embodiments, operation 503 is not optional, depending on how the subsequent fill is performed. Operation 503 can be expected to treat surfaces at or near the field region preferentially as discussed above. Then, in an operation 505, a parallel inhibition and deposition process is performed. Parallel inhibition and deposition refers to at least partial overlap of inhibition and deposition operations. In many embodiments, NH₃ or other thermal inhibition gas is co-flowed with a metal precursor and a reducing agent into the chamber during part or all of a chemical vapor deposition (CVD) process.

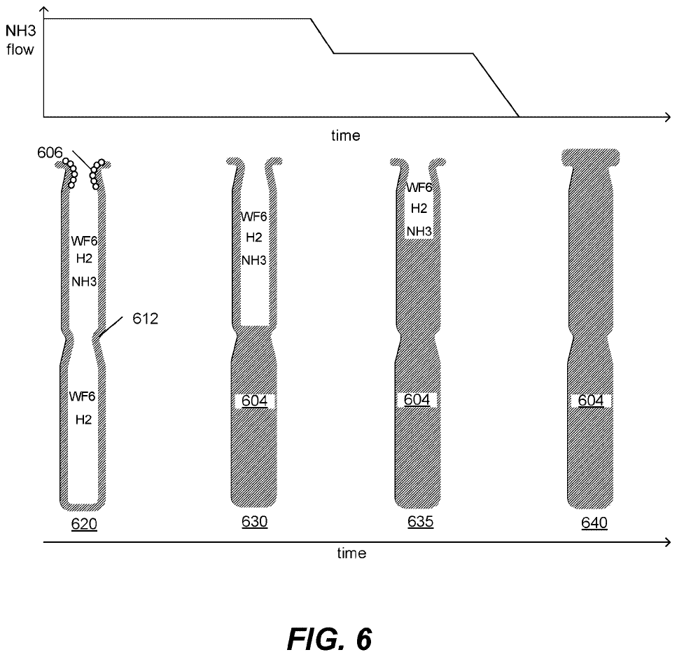

Flowing an inhibition gas during the fill process can increase an inhibition depth. The diffusion and depth of the inhibition can be controlled using flow rate and/or partial pressure of the inhibition gas and may change during the course of operation 505. An example is shown in FIG. 6. In FIG. 6, at 620, a feature having inhibited surfaces 606 is shown. This may be the feature as delivered to a deposition station, for example. An inhibition gas, NH₃ in the example of FIG. 6, is co-flowed with WF₆ and H₂. The NH₃ flow rate is sufficient so that NH₃ diffuses to slightly past constriction 612. WF₆ and H₂ diffuse to the bottom of the feature where they react and deposit tungsten 604. This is shown at 630.

Once the tungsten 604 passes the constriction 612, the NH₃ flow rate is reduced so that it is present at the top of the remaining unfilled portion of the feature, allowing WF₆ and H₂ to deposit at the bottom of the remaining unfilled portion of the feature. The NH₃ inhibits deposition at the top of the feature. This is shown at 635. The NH₃ flow rate is then reduced to zero, allowing complete fill of the feature as shown at 640.

Adding NH₃ or other inhibition gas during deposition enhances the selectivity of the metal growth, keeping the feature open longer, and enabling bottom-up growth. There may be a sidewall component to the growth in some embodiments. Selectivity vs depth can be altered after the initial inhibition after Dep1 using inhibition gas flow rate and/or partial pressure.

Referring back to FIG. 5, in some embodiments, operations 503 and 505 are performed in the same station. Residual NH₃ from operation 503 can further aid bottom-up fill.

As described above, in some embodiments, operation 503 is optional. If not performed, the first stage of operation 505 may serve as an initial inhibition operation. This can involve high metal precursor flow rate along with the inhibition gas. Reducing agent flow rate may be the same or lower than in subsequent deposition.

Flow sequence may vary during operation 505. In some embodiments, for example, two gases may be continuously flowed into the station while the third gas is pulsed. In some embodiments, one gas may be continuously flowed while the other two gases are pulsed. Pulsing generally refers to on/off but can also be from high flow to low flow.

Table 1 below shows examples of parallel CVD-Inhibition (PCI) processes that may be used to fill features with tungsten. The process examples are described further below. The sequences described may be used for other metal precursors, reducing agents, and inhibition gases.

TABLE 1
Parallel CVD-Inhibition Processes

| | Preceding | | | | |
|---|---|---|---|---|---|
| Process | Inhibition | Parallel CVD - Inhibition (PCI) Modes | | | |
| Example | Treatment | Mode | WF₆ Flow Rate | H₂ Flow Rate | NH₃ Flow Rate |
| 1 | Yes | Continuous | 200-1400 sccm | 6-12 slm | Ramping down, |
| | | Flow of WF₆, | | | up to 100 sccm |
| | | H₂, NH₃ | | | starting |
| 2 | Yes | Constant WF₆ | 200-1400 sccm | 1-12 slm | Pulsed and charged, |
| | | and H₂, pulsed | | | up to 100 sccm |
| | | NH₃ | | | starting |
| 3 | No | Continuous | 200-1400 sccm | 0-12 slm, | Ramping down, |
| | | Flow of WF₆, | | ramping up | up to 200 sccm |
| | | H₂, NH₃ | | | starting |
| 4 | No | Alternating | 200-1400 sccm | 0-12 slm | Ramping down, |
| | | between NH₃ | | | up to 200 sccm |
| | | and H₂ | | | starting |
| 5 | Optional | Continuous | 200-1400 sccm, | 0-12 sccm, | Continuously |
| | | flow NH₃, | pulsed and | pulsed and | ramping down, |
| | | pulsed WF₆ + | charged | charged | up to 200 sccm |
| | | H₂ | | | starting |
| 6 | Optional | Continuous | 200-1400 sccm, | 1-12 slm | Charged and pulsed, |
| | | flow H₂, | pulsed and | | up to 100 sccm |
| | | pulsed WF₆ + | charged | | starting |
| | | NH₃ | | | |

Flow rates can deviate from those in Table 1 based on the particular apparatus used, the substrate size, deposition rate, and other process parameters. The relative amounts of the different gases can be extrapolated to various embodiments. Notably, the amount of NH₃ or other inhibition gas is significantly lower than that of H₂ or other reducing agent. As a result, metal rather than metal nitride is deposited during the deposition.

Example temperatures for the processes above range from 350° C. to 490° C. This may vary for different reactants. Example chamber pressures range from 10 to 90 Torr.

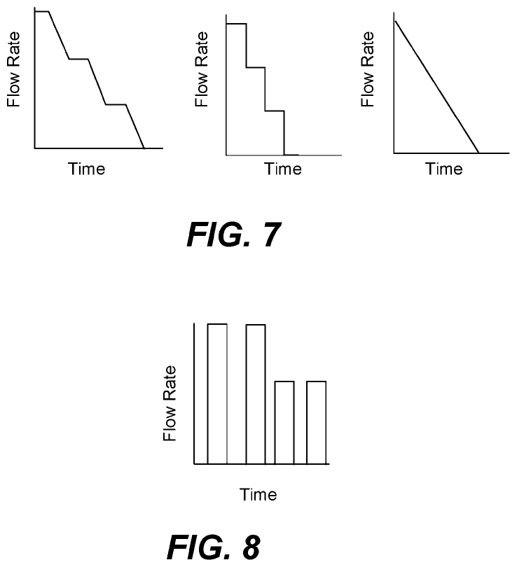

In many of the examples, a reactant is ramped down or up. This may be done in a step wise or continuous fashion and with or without plateaus at various stages. Examples of ramp down profiles are shown in FIG. 7. The duration of each stage, slope, and change in flow rate may vary or be constant from stage to stage. A ramp up in gas flow may similarly take various forms depending on the geometry of the structure and the apparatus used.

In many of the examples, a flow is pulsed and charged. In this manner, a pressurized pulse of the reactant or inhibition gas can be introduced to the chamber. Charge volumes are described further below. Diffusion depth can be modulated by varying the charge volume pressure in addition to or instead of flow rate.

Process 1 has a continuous NH₃ flow with ramping down. An inhibition process is performed prior to the PCI process. NH₃ is co-flowed with WF₆ and H₂, though the NH₃ is ramped down. Examples of ramp down flow profiles are shown in FIGS. 6 and 7.

Process 2 has a pulsed NH₃ flow. An example of a pulsed flow with ramp down is shown in FIG. 8. As indicted above, a pressurized line or charge volume can be used to deliver a pressurized pulse, with the pressure modulated in addition or instead of the flow rate to module the depth of inhibition. Process 2 may reduce NH₃ usage as compared to Process 1, while maintaining NH₃ concentration in the feature. Like Process 1, Process 2 involves an initial inhibition treatment without forming tungsten.

Process 3 is performed without an initial inhibition treatment. PCI involves ramping down of NH₃, ramping up of H₂, and constant WF₆. The relatively low H₂ at the beginning of the process provides an initial inhibition effect. The NH₃ may be started from a higher volumetric flow rate than a process that uses an initial inhibition.

Process 4 is performed with constant WF₆ and alternating NH₃ and H₂. In this manner, the process can alternate from favoring inhibition to favoring deposition, with as many cycles as appropriate for the feature. NH₃ can be ramped down over the whole process.

Process 5 is performed with an optional initial inhibition. NH₃ is flowed continuously with a WF₆+H₂ co-flow pulsed. NH₃ is ramped down as described above. In an alternate embodiment, alternate pulses of WF₆ and H₂ may be used instead of a co-flow. This may result in a more ALD-type of surface-mediated deposition.

Process 6 involves flowing H₂ continuously while pulsing a WF₆+NH₃ co-flow. Flowing H₂ has a de-inhibiting effect, which may be useful to tailor the deposition profile. In an alternate embodiment, alternate pulses of WF₆ and NH₃ may be used instead of a co-flow.

In embodiments in which an initial inhibition is performed, for example, by flow NH₃ or other inhibition gas with or without WF₆ or other metal precursor (with no reducing agent), the process may transition from the inhibition to the PCI process without an intervening purge operation.

Co-flow can involve synchronized pulsing in which valves allowing flow of each gas are opened at the same time or timed such that the gases reach the process station or a mixing chamber at the same time.

### Metal-Containing Precursors

While WF₆ is used as an example of a tungsten-containing precursor in the above description, other tungsten-containing precursors may be suitable for performing disclosed embodiments. For example, a metal-organic tungsten-containing precursor may be used. Organometallic precursors and precursors that are free of fluorine, such as MDNOW (methylcyclopentadienyl-dicarbonylnitrosyl-tungsten) and EDNOW (ethylcyclopentadienyl-dicarbonylnitrosyl-tungsten) may also be used. Chlorine-containing tungsten precursors (WClₓ) such as tungsten pentachloride (WCl₅) and tungsten hexachloride (WCl₆) may be used.

To deposit molybdenum (Mo), Mo-containing precursors including molybdenum hexafluoride (MoF₆), molybdenum pentachloride (MoCl₅), molybdenum dichloride dioxide (MoO₂Cl₂), molybdenum tetrachloride oxide (MoOCl₄), and molybdenum hexacarbonyl (Mo(CO)₆) may be used.

To deposit ruthenium (Ru), Ru-precursors may be used. Examples of ruthenium precursors that may be used for oxidative reactions include (ethylbenzyl)(1-ethyl-1,4-cyclohexadienyl)Ru(0), (1-isopropyl-4-methylbenzyl)(1,3-cyclohexadienyl)Ru(0), 2,3-dimethyl-1,3-butadienyl)Ru(0)tricarbonyl, (1,3-cyclohexadienyl)Ru(0)tricarbonyl, and (cyclopentadienyl)(ethyl)Ru(II)dicarbonyl. Examples of ruthenium precursors that react with non-oxidizing reactants are bis(5-methyl-2,4-hexanediketonato)Ru(II)dicarbonyl and bis(ethylcyclopentadienyl)Ru(II).

To deposit cobalt (Co), cobalt-containing precursors including dicarbonyl cyclopentadienyl cobalt (I), cobalt carbonyl, various cobalt amidinate precursors, cobalt diazadienyl complexes, cobalt amidinate/guanidinate precursors, and combinations thereof may be used.

The metal-containing precursor may be reacted with a reducing agent as described above. In some embodiments, H₂ is used as a reducing agent for bulk layer deposition to deposit high purity films.

### Nucleation Layer Deposition

In some implementations, the methods described herein involve deposition of a nucleation layer prior to deposition of a bulk layer. For example, deposition of a conformal layer in a Dep1 operation may involve deposition of a nucleation layer followed by ALD of a thin bulk layer.

A nucleation layer is typically a thin conformal layer that facilitates subsequent deposition of bulk material thereon. For example, a nucleation layer may be deposited prior to any fill of the feature and/or at subsequent points during fill of the feature (e.g., via interconnect) on a wafer surface. For example, in some implementations, a nucleation layer may be deposited following etch of tungsten in a feature, as well as prior to initial tungsten deposition.

In certain implementations, the nucleation layer is deposited using a pulsed nucleation layer (PNL) technique. In a PNL technique to deposit a tungsten nucleation layer, pulses of a reducing agent, optional purge gases, and tungsten-containing precursor are sequentially injected into and purged from the reaction chamber. The process is repeated in a cyclical fashion until the desired thickness is achieved. PNL broadly embodies any cyclical process of sequentially adding reactants for reaction on a semiconductor substrate, including atomic layer deposition (ALD) techniques. Nucleation layer thickness can depend on the nucleation layer deposition method as well as the desired quality of bulk deposition. In general, nucleation layer thickness is sufficient to support high quality, uniform bulk deposition. Examples may range from 10 Å-100 Å.

The methods described herein are not limited to a particular method of nucleation layer deposition but include deposition of bulk film on nucleation layers formed by any method including PNL, ALD, CVD, and physical vapor deposition (PVD). Moreover, in certain implementations, bulk tungsten may be deposited directly in a feature without use of a nucleation layer. For example, in some implementations, the feature surface and/or an already-deposited under-layer supports bulk deposition. In some implementations, a bulk deposition process that does not use a nucleation layer may be performed.

In various implementations, nucleation layer deposition can involve exposure to a metal precursor as described above and a reducing agent. Examples of reducing agents can include boron-containing reducing agents including diborane (B₂H₆) and other boranes, silicon-containing reducing agents including silane (SiH₄) and other silanes, hydrazines, and germanes. In some implementations, pulses of metal-containing can be alternated with pulses of one or more reducing agents, e.g., S/W/S/W/B/W, etc., W representing a tungsten-containing precursor, S represents a silicon-containing precursor, and B represents a boron-containing precursor. In some implementations, a separate reducing agent may not be used, e.g., a tungsten-containing precursor may undergo thermal or plasma-assisted decomposition.

### Bulk Deposition

As described above, bulk deposition may be performed across a wafer. In some implementations, bulk deposition can occur by a CVD process in which a reducing agent and a metal-containing precursor are flowed into a deposition chamber to deposit a bulk fill layer in the feature. Examples of PCI processes including CVD are described above. An inert carrier gas may be used to deliver one or more of the reactant streams, which may or may not be pre-mixed. Unlike PNL or ALD processes, this operation generally involves flowing the reactants continuously until the desired amount is deposited. In certain implementations, the CVD operation may take place in multiple stages, with multiple periods of continuous and simultaneous flow of reactants separated by periods of one or more reactant flows diverted. Bulk deposition may also be performed using ALD processes in which a metal-containing precursor is alternated with a reducing agent such as H₂. In some implementations, ALD may be used to deposit an initial bulk layer in a Dep1 process with CVD used for the remaining feature fill using a PCI process. In some implementations, ALD (with parallel inhibition) may be used for feature fill with CVD used for an overburden layer. In some implementations, ALD with parallel inhibition may be used for all of the bulk layer deposition.

It should be understood that the metal films described herein may include some amount of other compounds, dopants and/or impurities such as nitrogen, carbon, oxygen, boron, phosphorous, sulfur, silicon, germanium and the like, depending on the particular precursors and processes used. The metal content in the film may range from 20% to 100% (atomic) metal. In many implementations, the films are metal-rich, having at least 50% (atomic) metal, or even at least about 60%, 75%, 90%, or 99% (atomic) metal. In some implementations, the films may be a mixture of metallic or elemental metal (e.g., W, Mo, Co, or Ru) and other metal-containing compounds such as tungsten carbide (WC), tungsten nitride (WN), molybdenum nitride (MoN) etc. CVD and ALD deposition of these materials can include using any appropriate precursors as described above.

### Inhibition of Metal Nucleation

Plasma inhibition processes involve exposure to a plasma generated from a nitrogen containing compound, such as N₂. Plasma power, chamber pressure, and/or process gases may be pulsed in some embodiments.

The processes described above use thermal inhibition in many embodiments. Thermal inhibition processes generally involve exposing the feature to a nitrogen-containing compound such as ammonia (NH₃) or hydrazine (N₂H₄) to non-conformally inhibit the feature near the feature opening. In some embodiments, the thermal inhibition processes are performed at temperatures ranging from 250° C. to 450° C. At these temperatures, exposure of a previously formed tungsten or other layer to NH₃ results in an inhibition effect. Other potentially inhibiting chemistries such as nitrogen (N₂) and/or hydrogen (H₂) may be used for thermal inhibition at higher temperatures (e.g., 900° C.). For many applications, however, these high temperatures exceed the thermal budget. In addition to ammonia, other hydrogen-containing nitriding agents such as hydrazine may be used at lower temperatures appropriate for back end of line (BEOL) applications. During thermal inhibition, a metal precursor may be flowed with the inhibition gas or in alternating pulses with the gas. These other inhibition gases may be used instead of NH₃ in the processes described above.

In addition to the surfaces described above, nucleation may be inhibited on liner/barrier layers surfaces such as TiN and/or WN surfaces. Any chemistry that passivates these surfaces may be used. Inhibition chemistry can also be used to tune an inhibition profile, with different ratios of active inhibiting species used. For example, for inhibition of W surfaces, nitrogen may have a stronger inhibiting effect than hydrogen; adjusting the ratio of N₂ and H₂ gas in a forming gas can be used to tune a profile.

In certain implementations, the substrate can be heated up or cooled down before inhibition. A predetermined temperature for the substrate can be selected to induce a chemical reaction between the feature surface and inhibition species and/or promote adsorption of the inhibition species, as well as to control the rate of the reaction or adsorption. For example, a temperature may be selected to have high reaction rate such that more inhibition occurs near the gas source.

After inhibition, the inhibition effect may be modulated as described above. In the same or other embodiments, it may also be modulated by soaking it in a reducing agent or metal precursor, exposing it to a hydrogen-(H-)containing plasma, performing a thermal anneal, or exposing it an air, which can reduce the inhibition effect.

### Apparatus

Any suitable chamber may be used to implement the disclosed embodiments. Example deposition apparatuses include various systems, e.g., ALTUS® and ALTUS® Max, available from Lam Research Corp., of Fremont, California, or any of a variety of other commercially available processing systems.

In some embodiments, a first deposition may be performed at a first station that is one of two, five, or even more deposition stations positioned within a single deposition chamber. Thus, for example, hydrogen (H₂) and tungsten hexachloride (WF₆) may be introduced in alternating pulses to the surface of the semiconductor substrate, at the first station, using an individual gas supply system that creates a localized atmosphere at the substrate surface. Another station may be used for inhibition treatment+PCI. In some embodiments, the inhibition may be performed in a separate module.

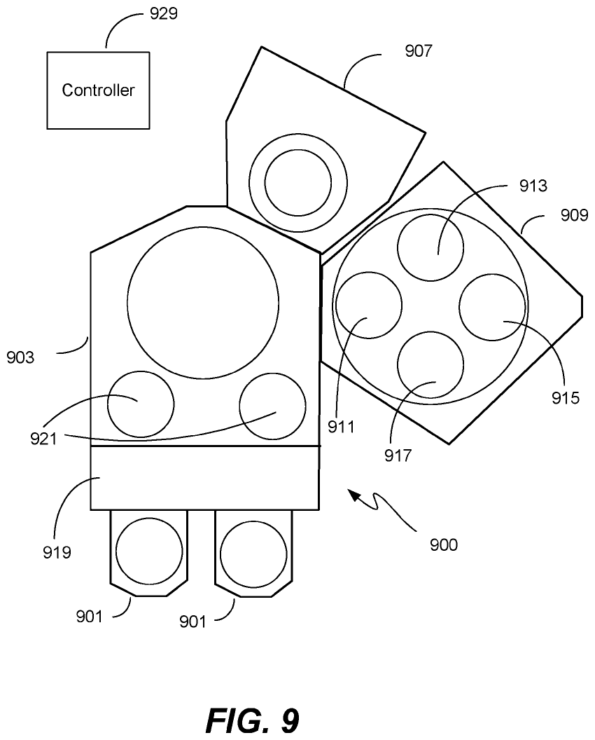

FIG. 9 is a schematic of a process system suitable for conducting deposition processes in accordance with embodiments. The system 900 includes a transfer module 903. The transfer module 903 provides a clean, pressurized environment to minimize risk of contamination of substrates being processed as they are moved between various reactor modules. Mounted on the transfer module 903 is a multi-station reactor 909 capable of performing ALD, CVD, and treatments such as inhibition treatment and de-inhibition treatment according to various embodiments. Multi-station reactor 909 includes multiple stations 911, 913, 915, and 917 that may sequentially or in parallel perform operations in accordance with disclosed embodiments. For example, multi-station reactor 909 may be configured such that station 911 performs a W, Mo, Co, or Ru nucleation layer deposition using a metal precursor and a boron- or silicon-containing reducing agent followed by an ALD W, Mo, Co, or Ru bulk deposition of a conformal layer using H₂ as reducing agent (Dep1), and station 913 performs an inhibition and a PCI process using a metal precursor, H₂, and NH₃. Stations 915 and 917, respectively, can run each process in parallel. In another example, station 911 may perform nucleation layer deposition, station 913 may perform bulk deposition of a conformal layer, station 915 may perform inhibition, and station 917 may perform PCI. Alternatively, stations 915 and 917 may both perform both inhibition and PCI (in parallel). Stations may include a heated pedestal or substrate support, one or more gas inlets or showerhead or dispersion plate.

Returning to FIG. 9, also mounted on the transfer module 903 may be one or more single or multi-station modules 907 capable of performing plasma or chemical (non-plasma) pre-cleans, plasma or non-plasma inhibition operations, other deposition operations, or etch operations. The module may also be used for various treatments to, for example, prepare a substrate for a deposition process. The system 900 also includes one or more wafer source modules 901, where wafers are stored before and after processing. An atmospheric robot (not shown) in the atmospheric transfer chamber 919 may first remove wafers from the source modules 901 to loadlocks 921. A wafer transfer device (generally a robot arm unit) in the transfer module 903 moves the wafers from loadlocks 921 to and among the modules mounted on the transfer module 903.

In various embodiments, a system controller 929 is employed to control process conditions during deposition. The controller 929 will typically include one or more memory devices and one or more processors. A processor may include a CPU or computer, analog and/or digital input/output connections, stepper motor controller boards, etc.

The controller 929 may control all the activities of the deposition apparatus. The system controller 929 executes system control software, including sets of instructions for controlling the timing, mixture of gases, chamber pressure, chamber temperature, wafer temperature, radio frequency (RF) power levels, wafer chuck or pedestal position, and other parameters of a particular process. Other computer programs stored on memory devices associated with the controller 929 may be employed in some embodiments.

Typically, there will be a user interface associated with the controller 929. The user interface may include a display screen, graphical software displays of the apparatus and/or process conditions, and user input devices such as pointing devices, keyboards, touch screens, microphones, etc.

System control logic may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe and may be entered utilizing the user interface.

Signals for monitoring the process may be provided by analog and/or digital input connections of the system controller 929. The signals for controlling the process are output on the analog and digital output connections of the deposition apparatus 900.

The system software may be designed or configured in many ways. For example, various chamber component subroutines or control objects may be written to control operation of the chamber components necessary to carry out the deposition processes in accordance with the disclosed embodiments. Examples of programs or sections of programs for this purpose include substrate positioning code, process gas control code, pressure control code, and heater control code.

In some implementations, a controller 929 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller 929, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller 929, in some implementations, may be a part of or coupled to a computer that is integrated with, coupled to the system, otherwise networked to the system, or a combination thereof. For example, the controller 929 may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus, as described above, the controller may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a CVD chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

The controller 929 may include various programs. A substrate positioning program may include program code for controlling chamber components that are used to load the substrate onto a pedestal or chuck and to control the spacing between the substrate and other parts of the chamber such as a gas inlet and/or target. A process gas control program may include code for controlling gas composition, flow rates, pulse times, and optionally for flowing gas into the chamber prior to deposition in order to stabilize the pressure in the chamber. A pressure control program may include code for controlling the pressure in the chamber by regulating, e.g., a throttle valve in the exhaust system of the chamber. A heater control program may include code for controlling the current to a heating unit that is used to heat the substrate. Alternatively, the heater control program may control delivery of a heat transfer gas such as helium to the wafer chuck.

Examples of chamber sensors that may be monitored during deposition include mass flow controllers, pressure sensors such as manometers, and thermocouples located in the pedestal or chuck. Appropriately programmed feedback and control algorithms may be used with data from these sensors to maintain desired process conditions.

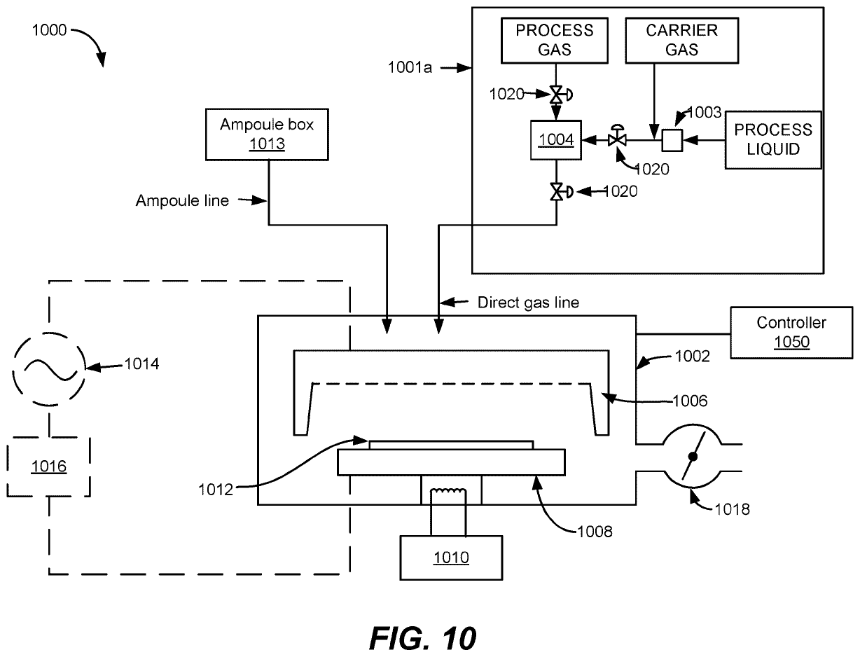

FIG. 10 depicts a schematic illustration of an embodiment of a process station 1000 having a process chamber 1002 for maintaining a low-pressure environment. In some embodiments, a plurality of process stations may be included in a common low-pressure process tool environment. For example, FIG. 9 depicts an embodiment of a multi-station reactor 909. In some embodiments, one or more hardware parameters of process station 1000, including those discussed in detail below, may be adjusted programmatically by one or more computer controllers 1050. In some other embodiments, a process chamber may be a single station chamber.

Process station 1000 fluidly communicates with reactant delivery system 1001a for delivering process gases to a distribution showerhead 1006. Reactant delivery system 1001a includes a mixing vessel 1004 for blending and/or conditioning process gases, such as a metal precursor-containing gas, a hydrogen-containing gas, an inhibition gas, an argon or other carrier gas, or other reactant-containing gas, for delivery to showerhead 1006. One or more mixing vessel inlet valves 1020 may control introduction of process gases to mixing vessel 1004.

As an example, the embodiment of FIG. 10 includes a vaporization point 1003 for vaporizing liquid reactant to be supplied to the mixing vessel 1004. In some embodiments, vaporization point 1003 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 1004. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 1003. In one scenario, a liquid injector may be mounted directly to mixing vessel 1004. In another scenario, a liquid injector may be mounted directly to showerhead 1006.

In some embodiments, a liquid flow controller (LFC) upstream of vaporization point 1003 may be provided for controlling a mass flow of liquid for vaporization and delivery to process chamber 1002. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller. According to various embodiments, one or more charge volumes may be connected to the process gas supplies.

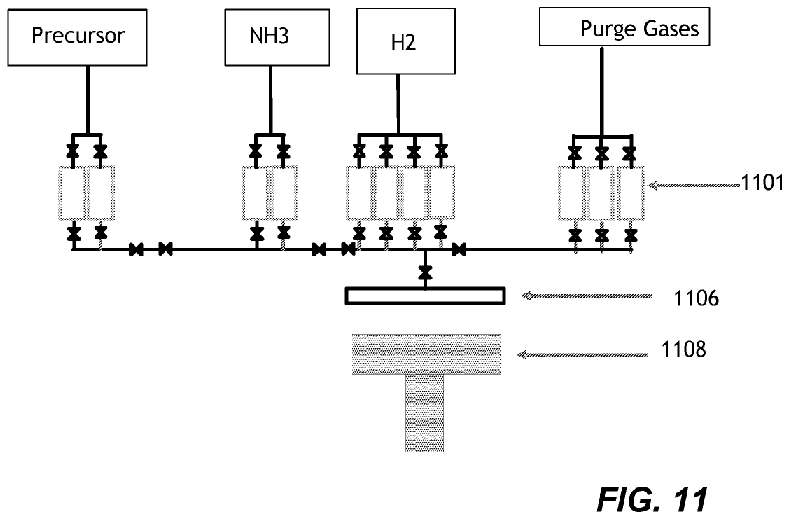

In some embodiments, the station may be equipped with one or more charge volumes. As described above, pulsing the reactant or inhibition gases may involve a charge volume. An example apparatus is shown in FIG. 11, in which four gas sources (precursor, NH₃ co-reactant, H₂, and purge gases) are each connected to charge volumes 1101. According to various embodiments, all or only subset of these gas sources may be connected to charge volumes. The charge volumes 1101 are used to build a pressurized volume of gas, which is then flowed into the process chamber. Gas from charge volumes 1101 is pressurized (e.g., to 300 Torr-700 Torr) and enters a chamber via showerhead 1106. A pedestal 1108 for supporting a wafer is also shown.

Returning to FIG. 10, showerhead 1006 distributes process gases toward substrate 1012. In the embodiment shown in FIG. 10, the substrate 1012 is located beneath showerhead 1006 and is shown resting on a pedestal 1008. Showerhead 1006 may have any suitable shape and may have any suitable number and arrangement of ports for distributing process gases to substrate 1012.

In some embodiments, pedestal 1008 may be raised or lowered to expose substrate 1012 to a volume between the substrate 1012 and the showerhead 1006. In some embodiments, pedestal 1008 may be temperature controlled via heater 1010. Pedestal 1008 may be set to any suitable temperature during operations for performing various disclosed embodiments. It will be appreciated that, in some embodiments, pedestal height may be adjusted programmatically by a suitable computer controller 1050. At the conclusion of a process phase, pedestal 1008 may be lowered during another substrate transfer phase to allow removal of substrate 1012 from pedestal 1008.

In some embodiments, a position of showerhead 1006 may be adjusted relative to pedestal 1008 to vary a volume between the substrate 1012 and the showerhead 1006. Further, it will be appreciated that a vertical position of pedestal 1008 and/or showerhead 1006 may be varied by any suitable mechanism within the scope of the present disclosure. In some embodiments, pedestal 1008 may include a rotational axis for rotating an orientation of substrate 1012. In some embodiments, one or more of these example adjustments may be performed programmatically by one or more suitable computer controllers 1050. The computer controller 1050 may include any of the features described below with respect to controller 1050 of FIG. 10.

If plasma is used during deposition or inhibition, showerhead 1006 and pedestal 1008 electrically communicate with a radio frequency (RF) power supply 1014 and matching network 1016 for powering a plasma. In some embodiments, the plasma energy may be controlled by controlling one or more of a process station pressure, a gas concentration, an RF source power, an RF source frequency, and a plasma power pulse timing. For example, RF power supply 1014 and matching network 1016 may be operated at any suitable power to form a plasma having a desired composition of radical species. Likewise, RF power supply 1014 may provide RF power of any suitable frequency. In some embodiments, RF power supply 1014 may be configured to control high- and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 1050 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., a metal precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of H₂, instructions for modulating the flow rate of a carrier or purge gas and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 1000 may be provided by butterfly valve 1018. As shown in the embodiment of FIG. 10, butterfly valve 1018 throttles a vacuum provided by a downstream vacuum pump (not shown). However, in some embodiments, pressure control of process station 1000 may also be adjusted by varying a flow rate of one or more gases introduced to the process station 1000.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

Unless otherwise stated, ranges in this disclosure are inclusive of the endpoints. For example, between 25:75-75:25 includes 25:75 and 75:25.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method comprising:
a) providing a feature to be filled with metal, the feature including a feature opening and sidewalls extending from the feature opening to a process station; and
b) exposing the feature to a metal precursor, a reducing agent, and a nitrogen-containing gas to fill the feature with metal, wherein the nitrogen-containing gas inhibits metal deposition on surfaces of the sidewalls it contacts.

2. The method of claim 1, wherein a flow of the nitrogen-containing gas is decreased as more metal is deposited in the feature.

3. The method of claim 1, further comprising, prior to (b), forming a liner of metal in the feature.

4. The method of claim 1, further comprising, prior to (b), exposing the feature to the nitrogen-containing gas without significant deposition to inhibit deposition of the metal near the feature opening.

5. The method of claim 1, wherein (b) comprises continuously co-flowing the metal precursor, the reducing agent, and the nitrogen-containing gas into the process station.

6. The method of claim 5, further comprising, prior to (b), exposing the feature to the nitrogen-containing gas without significant deposition to inhibit deposition of the metal near the feature opening.

7. The method of claim 4, wherein a flow of the reducing agent is ramped up and a flow of the nitrogen-containing gas is ramped down as (b) progresses.

8. The method of claim 1, wherein (b) comprises continuously flowing the metal precursor into the process station while pulsing the reducing agent and the nitrogen-containing gas in alternating sequence.

9. The method of claim 1, wherein (b) comprises continuously flowing the nitrogen-containing gas into the process station containing the substrate while pulsing the metal precursor and the reducing agent into the process station.

10. The method of claim 9, wherein the metal precursor and the reducing agent are pulsed together into the process station.

11. The method of claim 9, wherein pulses of the metal precursor and pulses of the reducing agent are alternated.

12. The method of claim 1, wherein (b) comprises continuously flowing the reducing agent into the process station containing the substrate while pulsing the metal precursor and nitrogen-containing gas into the process station.

13. The method of claim 12, wherein the metal precursor and nitrogen-containing gas are pulsed together into the process station.

14. The method of claim 12, wherein pulses of the metal precursor and pulses of the nitrogen-containing gas are alternated.

15. The method of claim 1, wherein the metal is one of a tungsten (W), molybdenum (Mo), ruthenium (Ru), or cobalt (Co).

16. The method of claim 1, wherein the nitrogen-containing gas is ammonia.

17. An apparatus comprising:
a process station comprising a showerhead to direct gases to a substrate support;
a controller configured to execute machine-readable instructions for filling a feature with metal, the instructions comprising instructions for:
(a) causing flowing of a metal precursor, a reducing agent, and a nitrogen-containing gas into the process station to fill the feature with metal.

18. The apparatus of claim 17, wherein the instructions for (a) cause continuous co-flowing of the metal precursor, the reducing agent, and the nitrogen-containing gas into the process station.

19. The apparatus of claim 17, wherein the instructions further comprise instructions for, prior to (a), causing flowing of the nitrogen-containing gas without flowing of the reducing agent to inhibit metal deposition near the feature opening.

20. The apparatus of claim 15, wherein instructions further comprise instructions for causing ramping up of flowing of the reducing agent flow and ramping down of flowing of the nitrogen-containing gas as (a) progresses.
